(19) United States
(12) Patent Application Publication
(10) Pub. No.: US 2015/0093887 A1
(43) Pub. Date: Apr. 2, 2015

(54) METHODS FOR REMOVING A NATIVE OXIDE LAYER FROM GERMANIUM SUSBTRATES IN THE FABRICATION OF INTEGRATED CIRCUITSI

(71) Applicant: GLOBALFOUNDRIES, INC., Grand Cayman (KY)

(72) Inventors: Bin Yang, San Carlos, CA (US); Shurong Liang, Poughkeepsie, NY (US); Kristina Young-Fisher, Clifton Park, NY (US); Kevin Kashefi, San Ramon, CA (US); Amol Joshi, Sunnyvale, CA (US); Salil Mujumdar, San Jose, CA (US); Abhijit Pethe, San Jose, CA (US); Albert Lee, Cupertino, CA (US); Ashish Bodke, San Jose, CA (US)

(73) Assignee: GLOBALFOUNDRIES, INC., Grand Cayman (KY)

(21) Appl. No.: 14/253,668

(22) Filed: Apr. 15, 2014

Related U.S. Application Data
(63) Continuation-in-part of application No. 14/044,376, filed on Oct. 2, 2013.

(51) Int. Cl. H01L 21/3065; H01L 21/02; H01L 21/28

(52) U.S. Cl. CPC H01L 21/3065; H01L 21/28255; H01L 21/02315
USPC 438/585; 438/694

(57) ABSTRACT

Methods for fabricating integrated circuits are provided in various exemplary embodiments. In one embodiment, a method for fabricating an integrated circuit includes providing a germanium-based semiconductor substrate including a GeOₓ layer formed thereon having a first thickness, removing a portion of the GeOₓ layer by exposing the semiconductor substrate to a NF₃/NH₃ plasma dry etch so as to reduce the first thickness of the GeOₓ layer to a second thickness, and depositing a high-k material over the GeOₓ layer of the semiconductor substrate.

### CROSS-REFERENCE TO RELATED APPLICATIONS

This application is a continuation-in-part of U.S. patent application Ser. No. 14/044,376, filed Oct. 2, 2013, the contents of which are incorporated by reference herein in their entirety.

### TECHNICAL FIELD

The present disclosure generally relates to methods for fabricating integrated circuits. More particularly, the presented disclosure relates to methods for removing native oxide layers from germanium substrates in the fabrication of integrated circuits.

### BACKGROUND

The majority of present day integrated circuits (ICs) are implemented by using a plurality of interconnected field effect transistors (FETs), also called metal oxide semiconductor field effect transistors (MOSFETs), or simply MOS transistors. An MOS transistor includes a gate electrode as a control electrode formed over a semiconductive substrate, and spaced apart source and drain electrodes within the substrate between which a current can flow. A control voltage applied to the gate electrode controls the flow of current through a channel in the semiconductive substrate between the source and drain electrodes.

The gain of an MOS transistor, usually defined by the transconductance (gₘ), is proportional to the mobility of the majority carrier in the transistor channel. The current carrying capability and hence the performance of an MOS transistor is proportional to the mobility of the majority carrier in the channel. With the continued scaling of modern MOSFETs, transistors fabricated using conventional bulk silicon substrates are approaching their fundamental limits with regard to carrier mobility. Thus, various other substrate materials have been investigated. One such material, germanium (Ge), exhibits carrier mobilities that are approximately two to four times higher than that of silicon.

In Ge-based MOSFETs, the “quality” of the MOS interface (i.e., the interface between the Ge substrate and the gate electrode, or the gate insulator below the gate electrode) is one of several factors that allow for the realization of the above-noted improved carrier mobility in the channel. As conventionally used in the art, the “quality” of the MOS interface refers to the diffusional stability of the interface, as well as the adhesion of the interfacial layers. In order to promote interfacial stability and adhesion, an interfacial layer (IL) is conventionally provided between the Ge substrate and the first layer of the gate insulator, for example a high-k layer (i.e., having a dielectric constant greater than the dielectric constant of silicon dioxide). While various interfacial layers have been investigated, germanium oxide (GeOₓ) is the most widely used material due to its ease of growth on Ge (thermal oxidation in an oxidizing environment, for example) as well as its ability to adhere to both Ge and various high-k materials, which themselves are often metal oxides (for example, Al₂O₃ or HfO₂).

In order to increase the carrier mobility performance of the transistor, it is desirable to provide an IL that is as thin as possible. While the presence of the IL aides in stability and adhesion at the MOS interface, the IL detrimentally contributes to a decrease in gate capacitance, which may harm transistor performance. A particular issue that is sometimes encountered when attempting to provide a thin GeOₓ IL is “native oxide” growth, i.e., GeOₓ that grows on the surface of a Ge substrate when exposed to an oxidizing ambient, such as air. As is appreciated by those having ordinary skill in the art, native oxide growth occurs at a much faster rate on Ge than on silicon-based substrates, and therefore is particularly problematic for the fabrication of Ge-based MOSFETs. Thus it is desirable to remove the native oxide layer in substantial part prior to the deposition of any part of the transistor overlying the Ge substrate, such as the high-k dielectric layer.

In the prior art, the removal of the native oxide on Ge substrates has conventionally been performed by applying an etchant chemistry, such as a dry etchant chemistry, to the substrate under either ambient pressure or vacuum conditions. If native oxide removal is performed under ambient conditions, some native oxide may grow back before the substrate is transported to subsequent processing steps (such as the deposition of the high-k dielectric material). Alternatively, where native oxide removal is performed under vacuum conditions, the transfer of the substrate from the vacuum chamber to a subsequent high-k dielectric material deposition chamber is difficult to perform in high-throughput semiconductor fabrication facilities due to the possible loss of vacuum conditions while transferring the substrate between fabrication tools.

Accordingly, it is desirable to provide improved methods for fabricating integrated circuits using Ge-based semiconductor substrates. Additionally, it is desirable to provide such methods that include steps for the removal of native oxide from the Ge-based substrate that are suitable for use in high-throughput semiconductor fabrication facilities. Furthermore, other desirable features and characteristics of the present disclosure will become apparent from the subsequent detailed description and the appended claims, taken in conjunction with the accompanying drawings and the foregoing technical field and background.

### BRIEF SUMMARY

Various exemplary methods for fabricating integrated circuits are provided. In one exemplary embodiment, a method for fabricating an integrated circuit includes providing a germanium-based semiconductor substrate including a GeOₓ layer formed thereon having a first thickness, removing a portion of the GeOₓ layer by exposing the semiconductor substrate to a NF₃/NH₃ plasma dry etch so as to reduce the first thickness of the GeOₓ layer to a second thickness, and depositing a high-k material over the GeOₓ layer of the semiconductor substrate.

In accordance with another exemplary embodiment, a method for fabricating an integrated circuit includes providing a germanium-based semiconductor substrate including a GeOx layer formed thereon having a first thickness of about 0.1 nm or greater and removing a portion of the GeOx layer by exposing the semiconductor substrate to a NF₃/NH₃ plasma dry etch in a first process chamber positioned on a first platform so as to reduce the first thickness of the GeOx layer to a second thickness of about 1 nm or less. Exposing the semiconductor substrate includes exposing the semiconductor substrate at a temperature of about 100° to about 400° C., a pressure of about 100 mTorr to about 5 Torr, and for a time period of about 15 seconds to about 60 minutes. Further the method includes depositing a high-k Al₂O₃ material over the GeOx layer of the semiconductor substrate using an atomic layer deposition process in a second process chamber positioned on the first platform.

In accordance with yet another exemplary embodiment, a method for fabricating an integrated circuit includes providing a germanium-based semiconductor substrate including a GeOₓ layer formed thereon having a first thickness of about 1 nm or greater and removing a portion of the GeOₓ layer by exposing the semiconductor substrate to a NF₃/NH₃ plasma dry etch in a first process chamber positioned on a first platform under a vacuum seal so as to reduce the first thickness of the GeOₓ layer to a second thickness of about 0.5 nm or less. Exposing the semiconductor substrate includes exposing the semiconductor substrate at a temperature of about 150° C. to about 200° C., a pressure of about 0.5 Torr to about 1.5 Torr, and for a time period of about 5 minutes to about 30 minutes. Further, the method includes transferring the semiconductor substrate from the first chamber to a second chamber on the first platform without breaking the vacuum seal, depositing a high-k Al₂O₃ material over the GeOₓ layer of the semiconductor substrate using an atomic layer deposition process in the second process chamber positioned on the first platform, and forming a metal gate stack over the high-k material.

### BRIEF DESCRIPTION OF THE DRAWINGS

The various embodiments will hereinafter be described in conjunction with the following drawing figures, wherein like numerals denote like elements, and wherein:

FIG. 1 illustrates, in cross section, a germanium-based semiconductor substrate having a native oxide (GeOₓ) layer formed thereon, in accordance with an exemplary embodiment;

FIG. 2 illustrates a semiconductor fabrication tool configured to remove portions of the native oxide layer illustrated in FIG. 1, in accordance with an exemplary embodiment;

FIG. 3 illustrates the germanium-based semiconductor substrate having a reduced-thickness native oxide layer subsequent to processing in the semiconductor fabrication tool illustrated in FIG. 2;

FIGS. 4-8 illustrate, in cross section, an integrated circuit structure and methods for fabricating an integrated circuit in accordance with various embodiments of the present disclosure; and

FIGS. 9-15 illustrate, in cross section, an integrated circuit structures and methods for fabricating integrated circuits in accordance with further embodiments of the present disclosure.

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following detailed description.

Embodiments of the present disclosure are directed to methods for removing a portion of a native oxide layer from a germanium substrate in the fabrication of integrated circuits. In order to remove the native oxide layer so as to leave remaining a desirably thin thickness thereof to serve as an interfacial layer, the germanium substrate is exposed to a NF₃/NH₃-containing plasma that etches the native oxide layer from the semiconductor substrate. The semiconductor fabrication equipment or “tool” that is used to perform the etch with the NF₃/NH₃ containing plasma may be configured on the same platform as the tool used to deposit a high-k dielectric layer over the interfacial layer, and as such there is no need to transport the semiconductor substrate between the fabrication step of forming the interfacial layer and forming the dielectric layer over the interfacial layer, thus reducing the possibility of undesirable native oxide formation on the semiconductor substrate between process steps. In particular, the substrate may be transported from the etching tool to the deposition tool without breaking the vacuum environment due to the tools being on the same platform. Methods in accordance with the present disclosure are easily integrated into existing integrated circuit fabrication process flows, and are suitable for use in both gate-first and gate-last process flows.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well-known process details.

The techniques and technologies described herein may be utilized to fabricate MOS transistor devices, including NMOS transistor devices, PMOS transistor devices, and CMOS transistor devices. In particular, the process steps described here may be utilized in conjunction with any semiconductor device fabrication process that forms gate structures for transistors. Although the term “MOS device” properly refers to a device having a metal gate electrode and an oxide gate insulator, that term will be used throughout this disclosure to refer to any semiconductor device that includes a conductive gate electrode that is positioned over a high-k or other gate dielectric, which in turn is positioned over a germanium-based semiconductor substrate.

FIG. 1 illustrates, in cross section, a germanium-based semiconductor substrate 104 having a native oxide (GeOₓ) layer 107 formed thereon in accordance with various embodiments of the present disclosure. In one example, semiconductor substrate 104 includes a crystalline Ge material configured in a (100) orientation. Native oxide layer 107 is commonly present on substrate 104 as a result of exposure to an oxidizing ambient, such as air, subsequent to the formation of substrate 104. Alternatively, oxide layer 107 may be present on substrate 104 as a result or thermal treatment of the substrate 104 in an oxidizing environment. Native oxide layer 107 has an initial thickness 120 from about 0.1 nanometers (nm) to about 3 nm or greater.

As noted above, while the presence of a GeOₓ interfacial layer is desirable to achieve a high quality MOS interface, the GeOₓ material undesirably decreases the gate capacitance of a transistor formed thereof if it is too thick. A decreased gate capacitance degrades the transconductance of an MOS device. As such, it is desirable to minimize the thickness of the oxide layer 107 to about 1 nm or less, for example about 5 angstroms (A) or less.

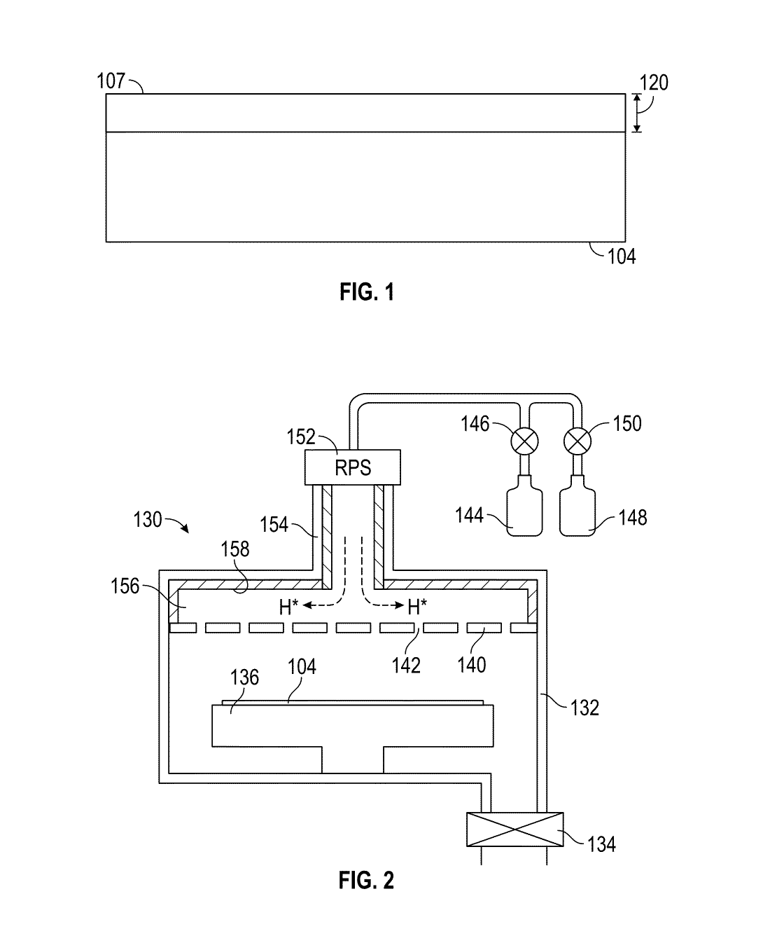

In order to reduce the thickness of oxide layer 107, in one embodiment, substrate 104 is delivered into a semiconductor fabrication tool that is configured to expose the substrate 104, and in particular the oxide layer 107 thereof, to a NF₃/NH₃ containing plasma for removing part of the oxide layer 107 so as to reduce the thickness of oxide layer 107 in a plasma-based dry etch process. As illustrated in a cross-sectional view in FIG. 2, in one embodiment, the semiconductor fabrication tool may be embodied as a remote plasma cleaning (i.e., dry etching) chamber 130 that includes a vacuum chamber 132 pumped by a vacuum pump system 134. A pedestal 136 within the chamber 132 supports the substrate 104 upon which the native oxide is to be reduced in thickness in opposition to a gas showerhead 140 supplying a process gas through a large number of apertures 142. The pedestal 136 includes a heater, not illustrated, to raise the temperature of the substrate 104 to a desired etching temperature.

The process gas, in one embodiment, is a combined nitrogen trifluoride/ammonia (NF₃/NH₃) gas, which is supplied from a NF₃ gas source 144 through a mass flow controller 146 and a NH₃ gas source 148 through another mass flow controller 150. The ratio of NF₃ to NH₃ in the combined gas may be from about 1:10 to about 10:1. Inert gasses such as Ar and N₂ also may be supplied in addition to the above-noted gas combination. A remote plasma generator system (RPS) 152 receives the gas and excites it into a plasma. The remote plasma generator 152 may be a pair of electrodes positioned on opposed sides of a delivery tube for the process gas. RPS 152 may be driven by an RF power source or an RF inductive coil around the delivery tube or other type of antenna. Of course, the use of other types of plasma generators is possible in other embodiments. The excited gas is delivered though supply tube 154 to a gas manifold 156 on the plasma-generator side of the showerhead 152. A liner 158 may cover the walls of the manifold 156 to ensure that excited gas does not escape the chamber 132. The excited gas is thus delivered uniformly through the showerhead 140 to the substrate 104 being cleaned.

In one embodiment, the remote plasma cleaning chamber 130 operates at a temperature from about 100° to about 400° C., for example from about 150° to about 200° C. The remote plasma cleaning chamber 130 operates at a pressure of about 100 mTorr to about 5 Torr, for example from about 0.5 Torr to about 1.5 Torr. Further, the remote plasma cleaning chamber 130 operates upon the substrate to be cleaned for a time period of about 15 second to about 60 minutes, for example from about 5 minutes to about 30 minutes.

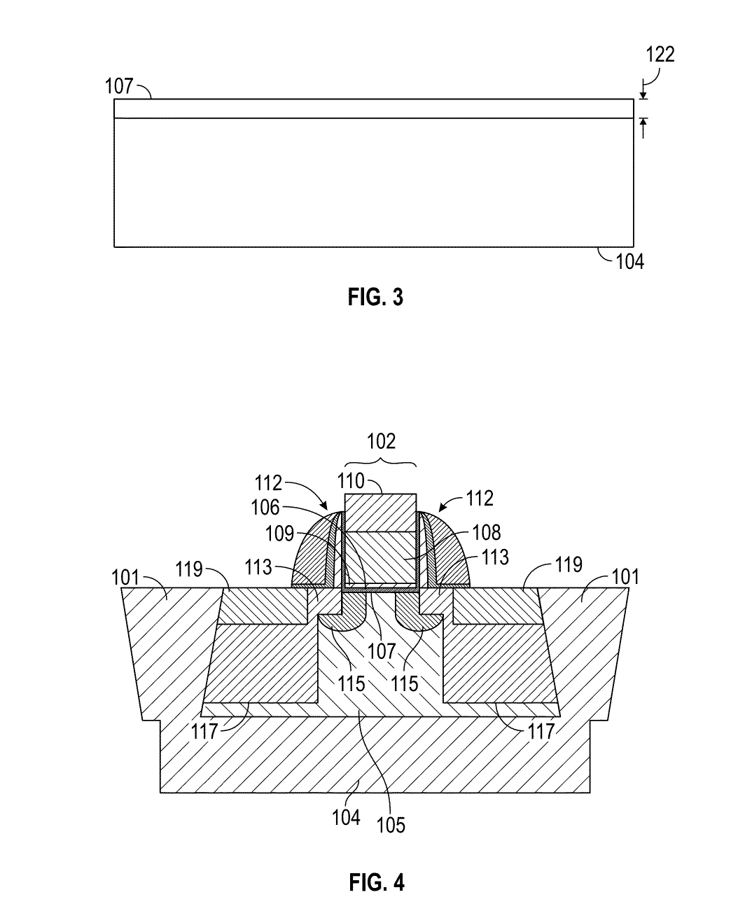

Upon processing in the chamber 130, the removal of portions of the native oxide layer 107 results in the native oxide layer 107 being reduced from the initial thickness 120 to a reduced thickness 122, as shown in FIG. 3. In one embodiment, thickness 122 is about 1 nm or less, for example about 5 angstroms (A) or less. The overall reduction in thickness, i.e., the amount of native oxide layer 107 removed, may be from about 1 Å to about 3 Å, such as about 2 Å. In this manner, the thickness 122 of layer 107 is suitable for use as an interfacial layer between the Ge-based substrate and a subsequently deposited high-k dielectric layer, as will be described in greater detail below, while desirably maximizing gate capacitance.

As initially noted above, the platform on which chamber 130 is configured supports tools for use in multiple fabrication steps, in addition to the remote plasma cleaning chamber 130 for the native oxide-removal step described above. In this manner, there is no need to break the vacuum seal in order to transport the substrate 104 between fabrication tools, which may result in the re-growth of native oxide. For example, the cleaning chamber 130 need not be provided on a dedicated platform, but may be combined on the same platform with other chambers, such as chambers used for etching such as inter-level dielectric etching, chemical vapor deposition (CVD), atomic layer deposition (ALD), or sputtering so that multiple operations may be performed in chambers on the same platform. In one exemplary embodiment, an ALD chamber for the atomic layer deposition of a high-k dielectric layer is also provided on the platform wherein chamber 130 is positioned. In this regard, the fabrication of the integrated circuit, including post-etching in the chamber 130, will now be described.

Reference is now made to FIG. 4, which illustrates the fabrication state of an integrated circuit device structure after the formation of a gate stack structure 102 overlying the Ge-based substrate 104, which is performed subsequent to the removal of a portion of the native oxide layer 107 (which will hereinafter be referred to as an interfacial layer (IL)) as described above. The integrated circuit is formed using well-known techniques and process steps (e.g., techniques and steps related to doping, photolithography and patterning, etching, material growth, material deposition, surface planarization, and the like) that will not be described in detail here.

As illustrated, one or more isolation regions 101 may be formed that extend into semiconductor material 104 to electrically isolate a plurality of transistors from one another. The isolation regions 101 are preferably formed by well-known shallow trench isolation (STI) techniques in which trenches are etched into semiconductor material 104, the trenches are filled with a dielectric material such as deposited silicon dioxide, and the excess silicon dioxide is removed by chemical mechanical planarization (CMP). STI regions 101 provide electrical isolation, as needed, between various devices of the integrated circuit that are to be formed.

In some embodiments, the gate stack structure 102 includes, without limitation: a gate insulation layer 106 overlying the IL 107 (although the elements of the figures are not drawn in proportion relative to each other, because of the thinness of IL 107, IL 107 appears as a line in the figures); a metal gate electrode element 108 overlying the gate insulation layer 106; and one or more spacer structures 112 adjacent to vertical sidewalls of the gate electrode element 108. The gate stack structure 102 may also include a capping layer 110 (which may be formed from a nitride, a silicide, or other material) formed over the gate electrode element 108. Further, the gate stack structure 102 may optionally include a work function modifying material 109, such as lanthanum (La) or aluminum (Al), which may be disposed in between the gate insulation layer 106 and the metal gate electrode element 108.

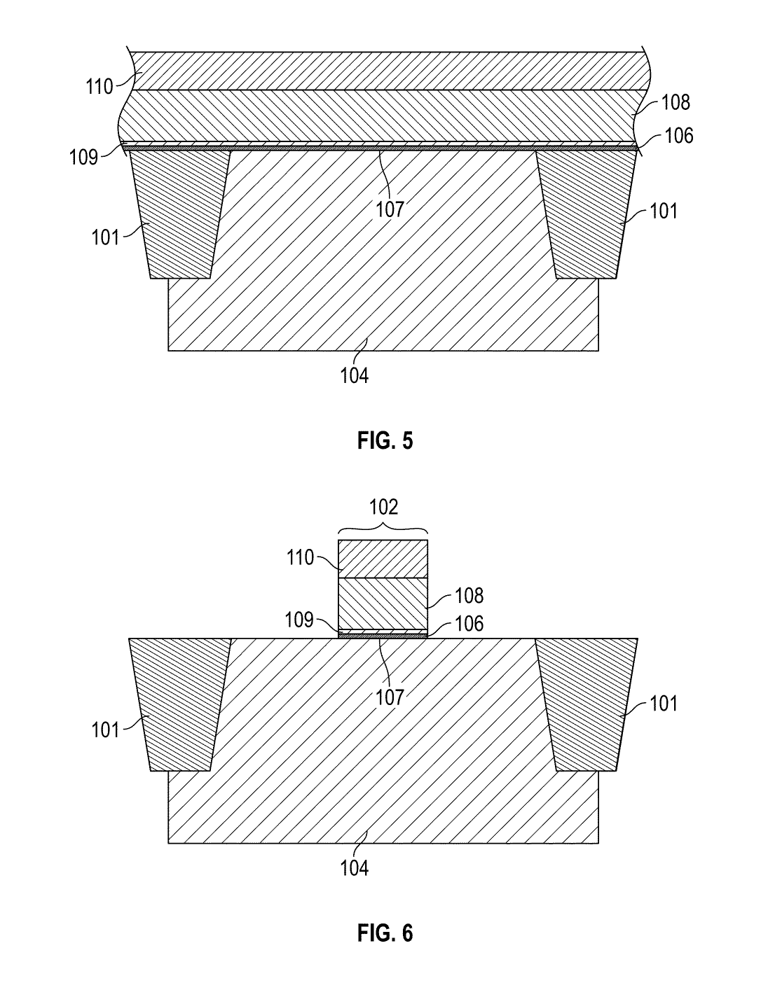

As initially noted above, the metal gate stack structure 102 may be formed using either “gate first” or “gate last” process flows, as are well-known in the art. In one embodiment, the metal gate stack structure 102 is formed using a “gate first” metal gate process flow as will be described in greater detail below with reference to FIG. 5. Formation of the metal gate stack 102, in a gate first process, begins with the formation of gate insulation layer 106. In order to prevent the re-growth of native oxide layer 107, the formation of the gate insulation layer may be performed in a deposition chamber on the same platform as the chamber 130 wherein the NF₃/NH₃ plasma oxide removal step was previously performed. The material used for the gate insulation layer 106 may be a high-k or other metal oxide, such as hafnium oxide or aluminum oxide. Layer 106 may be deposited, for example, by chemical vapor deposition (CVD), atomic layer deposition (ALD), low pressure chemical vapor deposition (LPCVD), or plasma enhanced chemical vapor deposition (PECVD) at a temperature from about 400° C. to about 900° C. The overall thickness of the gate insulation layer 106, including the combined thickness of all aluminum-based materials deposited, is from about 1 nm to about 5 nm. In an exemplary embodiment, the layer 106 is an ALD-deposited Al₂O₃ layer deposited from trimethyl aluminum (TMA) and ozone (O₃) precursors.

Continuing with the description of the exemplary gate first process flow, the work function modifying material 109 is optionally deposited subsequent to the formation of layer 106 and, as noted above, may include one or more of La and Al, for example, or other materials as are known in the art. Material 109 may be deposited using a suitable deposition technique such as atomic layer deposition (ALD), CVD, LPCVD, semi-atmospheric chemical vapor deposition (SACVD), or PECVD. The work function modifying material 109 may be deposited to a thickness sufficient to achieve the desired work function modification effect, such as from about 2 Å to about 2 nm.

Thereafter, the gate electrode element 108 may be formed by electroplating, CVD, ALD, or PVD. In some embodiments, the gate electrode element 108 is conformally deposited using CVD or ALD. The gate electrode element 108 may be formed to a thickness from about 5 nm to about 50 nm. The gate electrode element 108 may be a metal such as titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi), tungsten (W), and the like. In one embodiment, the gate electrode element 108 includes TiN. The capping layer 110 may thereafter be deposited using a material such as a polysilicon, a silicon nitride, or a silicide.

With reference now to FIG. 6, the gate stack structure 102 is formed using known photolithographic patterning and etching procedures. That is, a photoresist layer is deposited and then is exposed to an image pattern and treated with a developing solution to form pattern openings within the photoresist layer. With the openings thus formed, the deposited layer may be etched to form gate stack structure 102 by, for example, RIE.

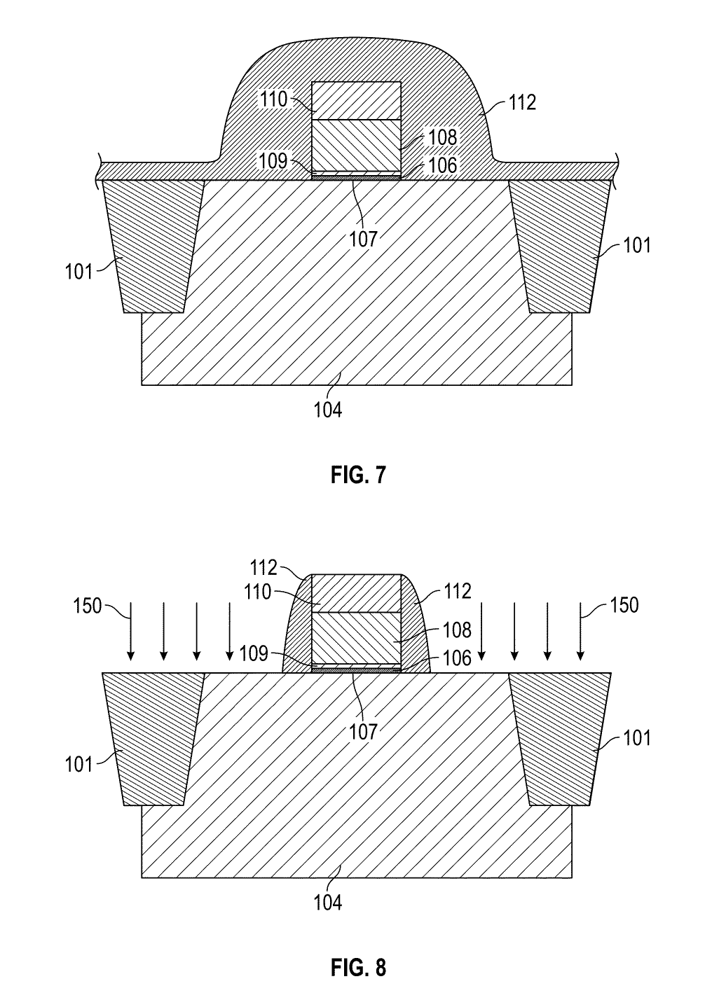

Turning to FIG. 7, the spacer structures 112 may thereafter be formed by depositing one or more dielectric materials over the germanium substrate 104 and the metal gate stack 102, where the dielectric material is an insulator, such as silicon nitride. The dielectric spacer material(s) may be deposited in a known manner by, for example, ALD, CVD, LPCVD, SACVD, or PECVD. The layer of dielectric spacer material is deposited to a thickness so that, after anisotropic etching, the spacer structures 112 formed from the layer have a thickness that is appropriate for the subsequent process steps described below. In some embodiments, the layer of dielectric spacer material is deposited to a thickness of about 5 nm to about 50 nm. The process continues, in accordance with an exemplary embodiment, with anisotropic etching of the layer(s) of dielectric spacer material(s) to form the spacer structures 112, as illustrated in FIG. 8. The layer(s) of dielectric spacer material(s) may be etched by, for example, RIE using a suitable etching chemistry.

The spacer structures 112 may be provided to protect the underlying semiconductor material 104 during ion implantation processes (illustrated by arrows 150 in FIG. 8) associated with the formation of source/drain extension implant regions 113, halo implant regions 115, and/or deep source/drain implant regions 117 (see FIG. 4), as is well understood. The spacer structures 112 may be removed after completion of the various ion implantation steps (and/or the completion of the process steps that utilize the spacer structures 112). Ion implantation to form the source/drain extension implant regions 113, halo implant regions 115, and/or deep source/drain implant regions 117 may be realized by exposing the semiconductor substrate to a dopant ion implantation process. For example, the implant regions may be formed by exposing germanium substrate 104 to an ionizing environment with an ionic dopant species that is directed downward towards the germanium substrate 104. Suitable dopants for this process may include the various ions of boron (B), aluminum (Al), and/or indium (In) to form a pFET, and phosphorus (P), arsenic (As), and/or antimony (Sb), to form an nFET. Further, source/drain implant regions 117 may be silicided (119) using conventional silicidation techniques known in the art. Subsequent to the ion implantation steps, the integrated circuit is formed substantially as illustrated and described above with regard to FIG. 4.

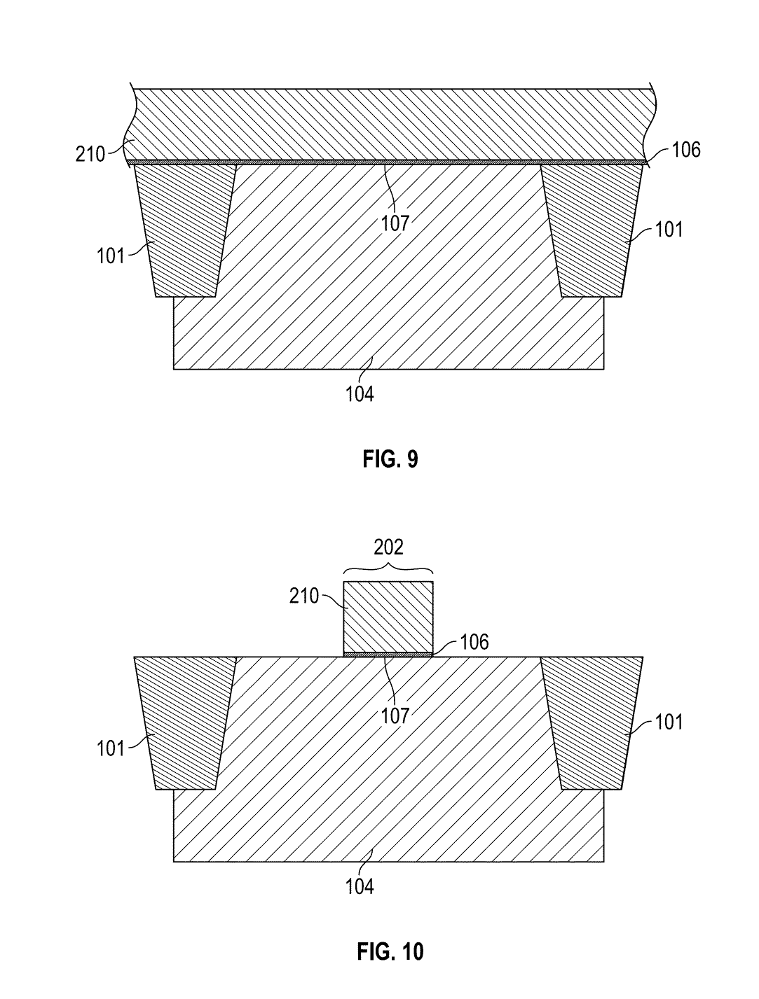

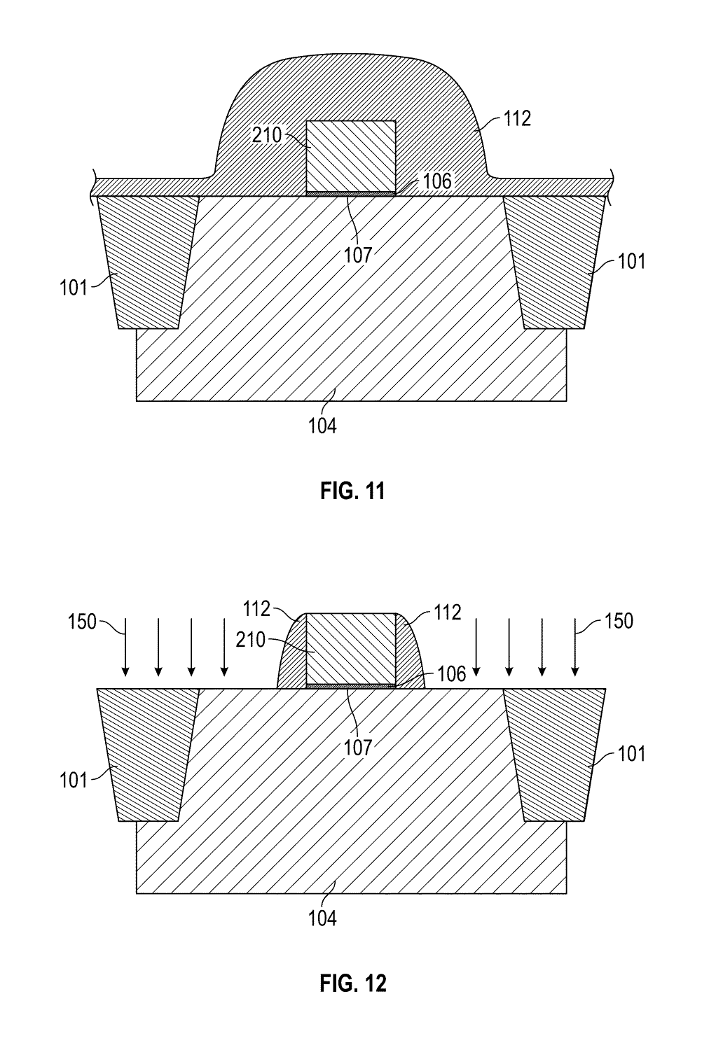

In an alternative embodiment, the metal gate stack 102 is fabricated using gate last or replacement metal gate (RMG) techniques that are well known in the art. For example, with reference to FIG. 9, the gate insulation layer 106 is provided over the IL 107 as described above with respect to FIG. 5. Thereafter, a temporary or “dummy” gate element 210 may be initially provided over the gate insulation layer 106 that includes polycrystalline silicon, although other replaceable materials could be used instead of polycrystalline silicon. Optionally, an etch stop layer of a suitable dielectric material (not shown) is first provided over the gate insulation layer 106 to protect the gate insulation layer during a subsequent etching step to remove the dummy gate element 210, as will be described in greater detail below. The dummy gate element 210 is provided by depositing a layer of polycrystalline silicon, e.g., using LPCVD by the hydrogen reduction of silane. Typically, the polycrystalline silicon layer will have a thickness within the range of about 50 nm to about 100 nm. With reference to FIG. 10, the polycrystalline silicon layer along with the gate insulation layer 106 is etched using an appropriate etch mask and etch chemistry to form dummy gate stack 202. Subsequently, with reference to FIGS. 11 and 12, the spacer structures 112, the source/drain extension implant regions 113, halo implant regions 115, and/or deep source/drain implant regions 117 may be formed using the procedures described above with regard to FIGS. 7 and 8.

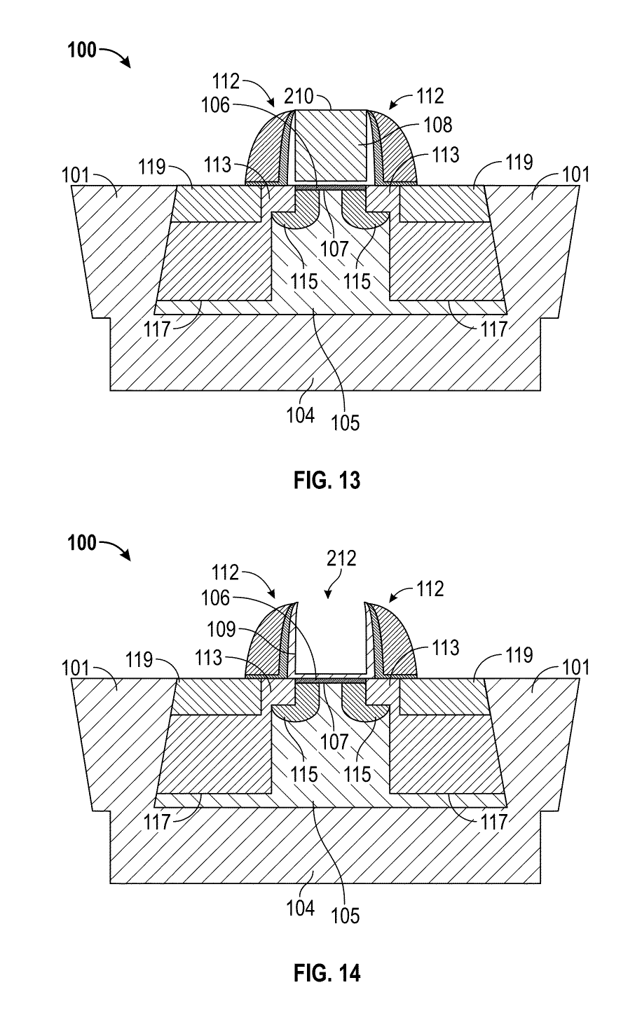

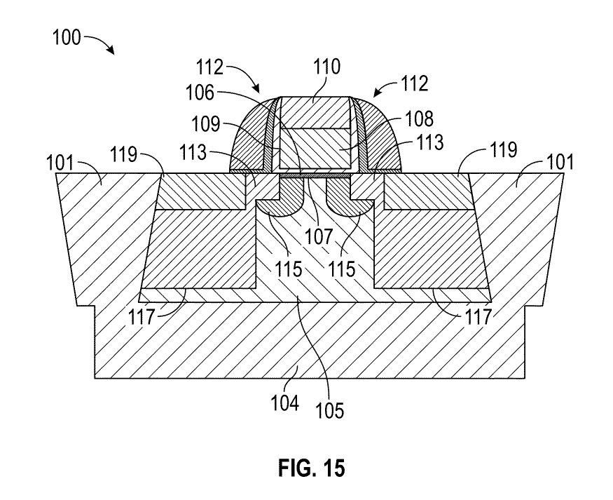

With reference now to FIGS. 13 and 14, the dummy gate element 210 is then removed using an appropriate etchant chemistry that selectively etches the material used for the temporary gate element, leaving a gate recess region 212. The etchant chemistry, the etching conditions, the duration of the etching process, and other factors may be controlled as needed to ensure that the temporary gate element 210 is removed. The replacement gate process continues by filling the gate recess region 212 with the optional work function modifying material 109, metal gate electrode element 108, and capping layer 110, as shown in FIG. 15.

Although not illustrated, with regard to any of the embodiments described above, the partially-formed integrated circuit is completed in a conventional manner by, for example, providing electrical contacts to the source and drain regions 117 and to the gate electrodes 108, depositing interlayer dielectrics, etching contact vias, filling the contact vias with conductive plugs, and the like as are well known to those of skill in the art of fabricating integrated circuits. Additional post-processing may include the formation of one or more metal layers (M1, M2, etc.) and interlayer dielectric layers therebetween to complete the various electrical connections in the integrated circuit. The present disclosure is not intended to exclude such further processing steps as are necessary to complete the fabrication of a functional integrated circuit, as are known in the art.

Thus, embodiments of the present disclosure provide methods for removing a native oxide layer from a germanium substrate in the fabrication of integrated circuits. The germanium substrate is exposed to a NF₃/NH₃-containing plasma that etches the native oxide layer from the semiconductor substrate so as to reduce its thickness. The semiconductor fabrication equipment or “tool” that is used to perform the etch with the NF₃/NH₃-containing plasma may also be configured on the same platform as the tool that is used to deposit a high-k dielectric layer over the interfacial layer, and as such there is no need to transport the semiconductor substrate between the fabrication step of forming the interfacial layer and forming the dielectric layer over the interfacial layer in a manner that breaks the vacuum seal, thus reducing the possibility of undesirable native oxide formation on the semiconductor substrate between process steps. The described methods are easily integrated into existing process flows, and are suitable for use in both gate-first and gate-last process flows.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method for fabricating an integrated circuit comprising:
providing a germanium-based semiconductor substrate comprising a GeOₓ layer formed thereon having a first thickness;
removing a portion of the GeOₓ layer by exposing the semiconductor substrate to a NF₃/NH₃ plasma dry etch so as to reduce the first thickness of the GeOₓ layer to a second thickness; and
depositing a high-k material over the GeOₓ layer of the semiconductor substrate.

2. The method of claim 1, wherein providing the semiconductor substrate comprises providing a semiconductor substrate comprising a native oxide layer.

3. The method of claim 1, wherein providing the semiconductor substrate comprises providing a semiconductor substrate comprising a GeOₓ layer having a thickness greater than about 0.1 nm.

4. The method of claim 1, wherein removing the portion of the GeOₓ layer comprises reducing the first thickness to a second thickness of about 1 nm or less.

5. The method of claim 4, wherein removing the portion of the GeOₓ layer comprises reducing the first thickness to a second thickness of about 0.5 nm or less.

6. The method of claim 1, wherein exposing the semiconductor substrate to a NF₃/NH₃ plasma dry etch comprises exposing the semiconductor substrate to the dry etch at a temperature from about 100° to about 400° C.

7. The method of claim 6, wherein exposing the semiconductor substrate to a NF₃/NH₃ plasma dry etch comprises exposing the semiconductor substrate to the dry etch at a temperature from about 150° to about 200° C.

8. The method of claim 1, wherein exposing the semiconductor substrate to a NF₃/NH₃ plasma dry etch comprises exposing the semiconductor substrate to the dry etch at a pressure from about 100 mTorr to about 5 Torr.

9. The method of claim 8, wherein exposing the semiconductor substrate to a NF₃/NH₃ plasma dry etch comprises exposing the semiconductor substrate to the dry etch at a pressure from about 0.5 Torr to about 1.5 Torr.

10. The method of claim 1, wherein exposing the semiconductor substrate to a NF₃/NH₃ plasma dry etch comprises exposing the semiconductor substrate to the dry etch for a time period from about 15 seconds to about 60 minutes.

11. The method of claim 10, wherein exposing the semiconductor substrate to a NF₃/NH₃ plasma dry etch comprises exposing the semiconductor substrate to the dry etch at a temperature from about 5 minutes to about 30 minutes.

12. The method of claim 1, wherein depositing the high-k material comprises depositing a metal oxide material.

13. The method of claim 12, wherein depositing the metal oxide material comprises depositing the metal oxide material using atomic layer deposition.

14. The method of claim 13, wherein depositing the metal oxide material comprises depositing Al₂O₃.

15. The method of claim 1, wherein exposing the semiconductor substrate to the NF₃/NH₃ plasma dry etch and depositing the high-k material are performed using the same processes platform.

16. The method of claim 1, wherein exposing the semiconductor substrate to the NF₃/NH₃ plasma dry etch comprises exposing the semiconductor substrate to an etchant wherein a ratio of NF₃ to NH₃ is from about 1:10 to about 10:1.

17. The method of claim 1, further comprising forming a metal gate stack over the high-k material in a gate-first process flow.

18. The method of claim 1, further comprising forming a metal gate stack over the high-k material in a gate-last process flow.

19. A method for fabricating an integrated circuit comprising:
providing germanium-based semiconductor substrate comprising a GeOₓ layer formed thereon having a first thickness of about 0.1 nm or greater;
removing a portion of the GeOₓ layer by exposing the semiconductor substrate to a NF₃/NH₃ plasma dry etch in a first process chamber positioned on a first platform so as to reduce the first thickness of the GeOₓ layer to a second thickness of about 1 nm or less, wherein exposing the semiconductor substrate comprises exposing the semiconductor substrate at a temperature of about 100° to about 400° C., a pressure of about 100 mTorr to about 5 Torr, and for a time period of about 15 seconds to about 60 minutes; and
depositing a high-k Al₂O₃ material over the GeOₓ layer of the semiconductor substrate using an atomic layer deposition process in a second process chamber positioned on the first platform.

20. A method for fabricating and integrated circuit comprising:
providing germanium-based semiconductor substrate comprising a GeOₓ layer formed thereon having a first thickness of about 1 nm or greater;
removing a portion of the GeOₓ layer by exposing the semiconductor substrate to a NF₃/NH₃ plasma dry etch in a first process chamber positioned on a first platform under a vacuum seal so as to reduce the first thickness of the GeOₓ layer to a second thickness of about 0.5 nm or less, wherein exposing the semiconductor substrate comprises exposing the semiconductor substrate at a temperature of about 150° C. to about 200° C., a pressure of about 0.5 Torr to about 1.5 Torr, and for a time period of about 5 minutes to about 30 minutes;
transferring the semiconductor substrate from the first chamber to a second chamber on the first platform without breaking the vacuum seal;
depositing a high-k Al₂O₃ material over the GeOₓ layer of the semiconductor substrate using an atomic layer deposition process in the second process chamber positioned on the first platform; and
forming a metal gate stack over the high-k material.
